(19) United States
(12) Patent Application Publication
(10) Pub. No.: US 2024/0324389 A1
(43) Pub. Date: Sep. 26, 2024

(54) DISPLAY APPARATUS

(71) Applicant: Samsung Display Co., Ltd., Yongin-si (KR)

(72) Inventors: Sunkwun Son, Yongin-si (KR); Donghee Shin, Yongin-si (KR); Raeyoung Kim, Yongin-si (KR); Sangyong No, Yongin-si (KR); Seungin Baek, Yongin-si (KR); Yongwoo Lee, Yongin-si (KR); Sangyun Lim, Yongin-si (KR); Younho Han, Yongin-si (KR)

(21) Appl. No.: 18/608,798

(22) Filed: Mar. 18, 2024

(30) Foreign Application Priority Data
Mar. 24, 2023 (KR) 10-2023-0039018
May 18, 2023 (KR) 10-2023-0064555

(51) Int. Cl. H10K 59/38; H10K 59/131

(52) U.S. Cl. CPC H10K 59/38; H10K 59/131

(57) ABSTRACT

A display apparatus includes a power line extending in a first direction, and in a second direction perpendicular to the first direction, and a first sub-pixel having a first pixel electrode, a second sub-pixel having a second pixel electrode, and a third sub-pixel having a third pixel electrode, which display different colors from each other, and which are arranged in a third direction crossing both the first direction and the second direction, in a plan view.

### CROSS-REFERENCE TO RELATED APPLICATION

The present application claims priority to, and the benefit of, Korean Patent Application No. 10-2023-0039018, filed on Mar. 24, 2023, and Korean Patent Application No. 10-2023-0064555, filed on May 18, 2023, in the Korean Intellectual Property Office, the contents of which in their entirety are herein incorporated by reference.

### BACKGROUND

### 1. Field

One or more embodiments relate to a display apparatus that may display high-quality images.

### 2. Description of Related Art

In a general display apparatus, such as an organic light-emitting display apparatus, thin-film transistors, connection electrodes, and wires are arranged in each (sub-)pixel to control luminance and the like of each (sub-)pixel. The thin-film transistors, the connection electrodes, and the wires form a multilayer structure.

The arrangement of a plurality of sub-pixels that emit different colors is a factor in displaying high-quality images.

### SUMMARY

One or more embodiments provide a display apparatus that may display a high-quality image through the disposition and arrangement of a plurality of sub-pixels.

However, such an aspect is an example, and the aspect to be solved by the disclosure is not limited thereto.

Additional aspects will be set forth in part in the description that follows and, in part, will be apparent from the description, or may be learned by practice of the presented embodiments of the disclosure.

According to one or more embodiments, a display apparatus includes a power line extending in a first direction, and in a second direction perpendicular to the first direction, and a first sub-pixel having a first pixel electrode, a second sub-pixel having a second pixel electrode, and a third sub-pixel having a third pixel electrode, which display different colors from each other, and which are arranged in a third direction crossing both the first direction and the second direction, in a plan view.

The second pixel electrode may overlap a portion of a first capacitor electrode of the first sub-pixel.

The first capacitor electrode may be electrically connected to a driving gate electrode of the first sub-pixel.

The first capacitor electrode may be at a layer under the driving gate electrode of the first sub-pixel.

The second pixel electrode may overlap a portion of an active layer of the first sub-pixel.

The active layer of the first sub-pixel may include a first active layer of the first sub-pixel partially overlapping a driving gate electrode of the first sub-pixel, wherein the first active layer of the first sub-pixel is electrically connected to the first pixel electrode.

A first capacitor electrode of the first sub-pixel may be at a lower layer under the first active layer of the first sub-pixel to overlap the first active layer of the first sub-pixel.

The second pixel electrode may overlap a portion of an active layer of the third sub-pixel.

A portion of the active layer of the third sub-pixel may be electrically connected to the third pixel electrode.

The display apparatus may further include a capacitor-blocking line between a first capacitor electrode of the first sub-pixel and a first capacitor electrode of the second sub-pixel.

The capacitor-blocking line may be electrically connected to the power line.

The capacitor-blocking line may be at a same layer as gate electrodes of the first sub-pixel, the second sub-pixel, and the third sub-pixel.

The power line may include a horizontal power line extending in the first direction, and a vertical power line extending in the second direction, and at a layer under the horizontal power line, and wherein the capacitor-blocking line is at a same layer as the horizontal power line.

The second sub-pixel may include a first active layer of the second sub-pixel partially overlapping a driving gate electrode of the second sub-pixel, wherein the first active layer of the second sub-pixel is between a first capacitor electrode of the second sub-pixel and a first capacitor electrode of the third sub-pixel.

The first active layer of the second sub-pixel may include a protruding portion extending in the first direction, wherein the protruding portion extends to a switching gate electrode of the second sub-pixel.

The third sub-pixel may include a first active layer of the third sub-pixel partially overlapping a driving gate electrode of the third sub-pixel, wherein the first active layer of the third sub-pixel is integrally formed with the first active layer of the second sub-pixel.

The driving gate electrode of the second sub-pixel and the driving gate electrode of the third sub-pixel may face each other.

The first active layer of the second sub-pixel may be electrically connected to the power line.

The display apparatus may further include a data line extending in the second direction, wherein the third pixel electrode overlaps a portion of the data line.

The display apparatus may further include a first color conversion unit in the first pixel electrode, and overlapping the first pixel electrode, a second color conversion unit in the second pixel electrode, and overlapping the second pixel electrode, and a third color conversion unit in the third pixel electrode, and overlapping the third pixel electrode.

Other aspects than those described above will become apparent from the following drawings, claims, and detailed description of the disclosure.

### BRIEF DESCRIPTION OF THE DRAWINGS

The above and other aspects of embodiments of the disclosure will be more apparent from the following description taken in conjunction with the accompanying drawings, in which:

FIG. 1 is a schematic plan view of a portion of a display apparatus according to one or more embodiments;

FIG. 2A is a schematic conceptual view of a portion of the display apparatus of FIG. 1;

FIG. 2B illustrates a color conversion unit of FIG. 2A;

FIG. 3 is an equivalent circuit diagram of a display element and a pixel circuit connected to the display element, included in the display apparatus of FIG. 1;

FIG. 4 is a schematic layout diagram showing the locations of transistors and a storage capacitor in one pixel in the display apparatus of FIG. 1;

FIGS. 5 to 8 are layout diagrams schematically showing, by layer, constituent elements, such as transistors, a storage capacitor, and the like, of the display apparatus illustrated in FIG. 4;

FIG. 9 is a schematic cross-sectional view taken along the line IX-IX′ of FIG. 4; and

FIG. 10 is a schematic layout diagram showing the locations of color conversion units in one pixel in a display apparatus.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The present disclosure covers all modifications, equivalents, and replacements within the idea and technical scope of the present disclosure. Further, each of the features of the various embodiments of the present disclosure may be combined or combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. In other instances, well-known structures and devices are shown in block diagram form to avoid unnecessarily obscuring various embodiments.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled,” or “directly on,” refers to one component directly connecting or coupling another component, or being on another component, without an intermediate component. In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expression such as “at least one of A and B” and “at least one of A or B” may include A, B, or A and B. As used herein, “or” generally means “and/or,” and the term “and/or” includes any and all combinations of one or more of the associated listed items. For example, the expression such as “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

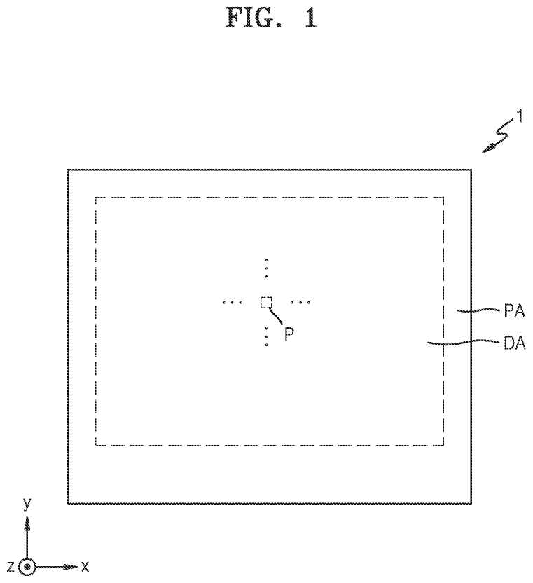

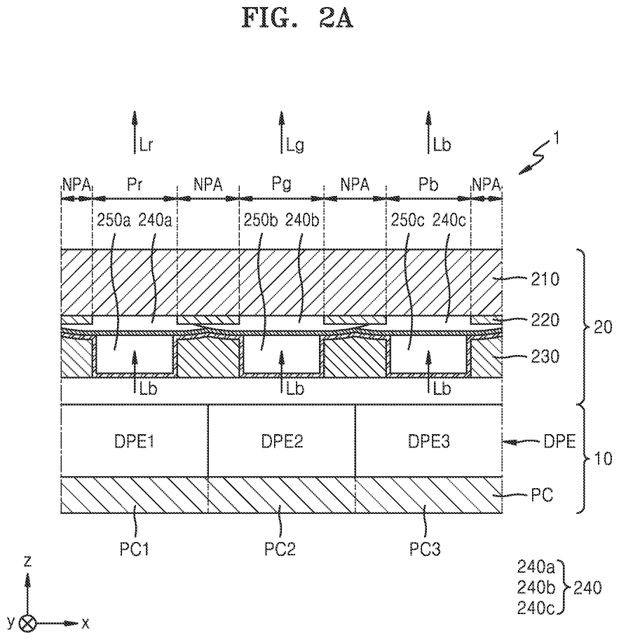

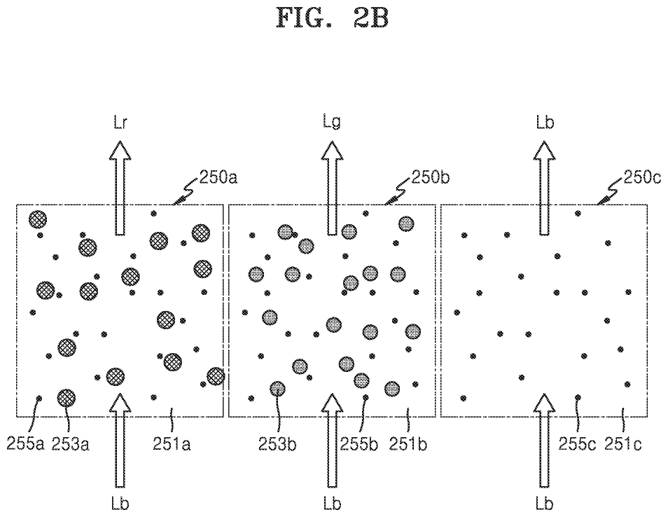

FIG. 1 is a schematic plan view of a portion of a display apparatus 1 according to one or more embodiments. FIG. 2A is a schematic conceptual view of a portion of the display apparatus 1 of FIG. 1, and FIG. 2B illustrates a color conversion unit of FIG. 2A

As illustrated in FIG. 1, the display apparatus 1 may include a display area DA in which a plurality of pixels P are arranged, and a peripheral area PA located outside the display area DA. The peripheral area PA may entirely surround the display area DA (e.g., in plan view).

The display area DA may have a polygonal shape including a rectangle, as illustrated in FIG. 1. For example, the display area DA may have a rectangular shape having the horizontal length greater than the vertical length, a rectangular shape having the horizontal length less than the vertical length, or a square shape.

Alternatively, the display area DA may have various shapes, such as a polygonal shape, an oval shape, or a circular shape, other than the rectangular shape.

The display apparatus 1 may include, as illustrated in FIG. 2A, a light-emitting panel 10 and a filter panel 20 stacked on each other. The light-emitting panel 10 may include a plurality of display elements DPE, and each of the display elements DPE is electrically connected to a corresponding circuit PC (hereinafter, referred to as the pixel circuit). The display elements DPE and the pixel circuits PC may be arranged in the display area DA.

In one or more embodiments, each of the display elements DPE may include a first display element DPE1, a second display element DPE2, and a third display element DPE3. Each of the first display element DPE1, the second display element DPE2, and the third display element DPE3 may be electrically connected to a first pixel circuit PC1, a second pixel circuit PC2, and a third pixel circuit PC3, respectively, and may be driven by the first pixel circuit PC1, the second pixel circuit PC2, and the third pixel circuit PC3, respectively.

Each of the first display element DPE1, the second display element DPE2, and the third display element DPE3 may emit light. In one or more embodiments, the first display element DPE1, the second display element DPE2, and the third display element DPE3 may emit the same light. For example, the first display element DPE1, the second display element DPE2, and the third display element DPE3 may emit any one of red light Lr, green light Lg, and blue light Lb. In another example, the first display element DPE1, the second display element DPE2, and the third display element DPE3 may emit any one of the red light Lr, the green light Lg, the blue light Lb, and white light. In one or more other embodiments, any one of the first display element DPE1, the second display element DPE2, and the third display element DPE3 and the other of the first display element DPE1, the second display element DPE2, and the third display element DPE3 may emit different light from each other. For example, the first display element DPE1 may emit the red light Lr, the second display element DPE2 may emit the green light Lg, and the third display element DPE3 may emit the blue light Lb. In the following description, a case in which the first display element DPE1, the second display element DPE2, and the third display element DPE3 are all emit the blue light Lb is mainly described in detail.

The filter panel 20 may be located on the light-emitting panel 10. The filter panel 20 may change the wavelength of light emitted from the light-emitting panel 10. In one or more embodiments, the filter panel 20 may be located on the display elements DPE. The filter panel 20 may change the wavelength of the light emitted from the display elements DPE. In one or more embodiments, while passing through the filter panel 20, the blue light Lb emitted from the first display element DPE1, the second display element DPE2, and the third display element DPE3 may be converted into the red light Lr, the green light Lg, and the blue light Lb, or may be transmitted without conversion. An area where the red light Lr is emitted may correspond to a red sub-pixel Pr. An area where the green light Lg is emitted may correspond to a green sub-pixel Pg. An area where the blue light Lb is emitted may correspond to a blue sub-pixel Pb.

The filter panel 20 may include an upper substrate 210, a first light-blocking layer 220, a second light-blocking layer 230, a filter 240, a first color conversion unit 250a, a second color conversion unit 250b, and a third color conversion unit 250c. The first light-blocking layer 220 may include a plurality of holes that are formed by removing portions corresponding to the red sub-pixel Pr, the green sub-pixel Pg, and the blue sub-pixel Pb. The first light-blocking layer 220 may include a material part that overlaps a non-pixel area NPA, and the material part may include various materials capable of reducing or absorbing light.

The second light-blocking layer 230 may be located on the first light-blocking layer 220. The second light-blocking layer 230 may include a material part that overlaps the non-pixel area NPA, and the material part may include various materials capable of absorbing light. The second light-blocking layer 230 may include the same material as, or a different material from, the first light-blocking layer 220. In one or more embodiments, the first light-blocking layer 220 and/or the second light-blocking layer 230 may include an opaque inorganic insulating material, such as a chromium oxide, a molybdenum oxide, or the like, or an opaque organic insulating material, such as black resin or the like.

The filter 240 may include a first filter 240a, a second filter 240b, and a third filter 240c. The first filter 240a may include pigment or dye of a first color (e.g., red). The second filter 240b may include pigment or dye of a second color (e.g., green). The third filter 240c may include pigment or dye of a third color (e.g., blue).

The first color conversion unit 250a, the second color conversion unit 250b, and the third color conversion unit 250c may be arranged between the filter 240 and the display elements DPE.

The first color conversion unit 250a may overlap the first filter 240a, and may convert the incident blue light Lb into the red light Lr. The first color conversion unit 250a may include a first photosensitive polymer 251a, first quantum dots 253a, and the first scattering particles 255a. The first quantum dots 253a and the first scattering particles 255a may be dispersed in the first photosensitive polymer 251a.

The first quantum dots 253a that are excited by the blue light Lb may emit the red light Lr having a wavelength longer than the wavelength of the blue light Lb. The first photosensitive polymer 251a may include an organic material having light transmissivity. The first scattering particles 255a may scatter the blue light Lb that is not absorbed by the first quantum dots 253a so as to excite more first quantum dots 253a, thereby increasing a color conversion efficiency. The first scattering particles 255a may include, for example, a titanium oxide (TiO₂), metal particles, or the like. The first quantum dots 253a may be selected from among a Group II-VI compound, a Group III-V compound, a Group IV-VI compound, a Group IV element, a Group IV compound, and a combination thereof.

The second color conversion unit 250b may overlap the second filter 240b, and may convert the incident blue light Lb into the green light Lg. The second color conversion unit 250b may include a second photosensitive polymer 251b, second quantum dots 253b, and second scattering particles 255b. The second quantum dots 253b and the second scattering particles 255b may be dispersed in the second photosensitive polymer 251b.

The second quantum dots 253b that are excited by the blue light Lb may emit the green light Lg having a wavelength longer than the wavelength of the blue light Lb. The second photosensitive polymer 251b may include an organic material having light transmissivity. The second scattering particles 255b may scatter the blue light Lb that is not absorbed by the second quantum dots 253b so as to excite more second quantum dots 253b, thereby increasing the color conversion efficiency. The second scattering particles 255b may include, for example, TiO₂, metal particles, or the like. The second quantum dots 253b may be selected from among a Group II-VI compound, a Group III-V compound, a Group IV-VI compound, a Group IV element, a Group IV compound, and a combination thereof. The quantum dots may each have a size of several nanometers, and the wavelength of light after the conversion may vary depending on the size of quantum dots.

The third color conversion unit 250c may overlap the third filter 240c, and may transmit the incident blue light Lb. The third color conversion unit 250c may include a third photosensitive polymer 251c and third scattering particles 255c. The third scattering particles 255c may be dispersed in the third photosensitive polymer 251c. The third photosensitive polymer 251c may include, for example, an organic material having light transmissivity, such as silicon resin, epoxy resin, and the like, and may include the same material as the first photosensitive polymer 251a and/or the second photosensitive polymer 251b. The third scattering particles 255c may scatter and emit the blue light Lb, and may include the same material as the first scattering particles 255a and/or the second scattering particles 255b.

The blue light Lb emitted from light-emitting panel 10 may be either color-converted or transmitted while passing through the first color conversion unit 250a, the second color conversion unit 250b, and the third color conversion unit 250c, and then may have increased color purity while passing through the filter 240. For example, the blue light Lb emitted from the first display element DPE1 may be color-converted into the red light Lr and filtered while passing through the first color conversion unit 250a and the first filter 240a. The blue light Lb emitted from the second display element DPE2 may be color-converted into the green light Lg and filtered while passing through the second color conversion unit 250b and the second filter 240b. The blue light Lb emitted from the third display element DPE3 may be transmitted and filtered while passing through the third color conversion unit 250c and the third filter 240c.

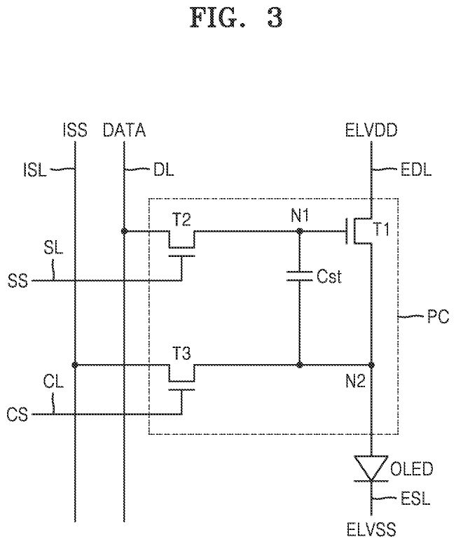

FIG. 3 is an equivalent circuit diagram of one of the display elements DPE, and the pixel circuit PC connected to the display element DPE, which are included in the display apparatus 1 of FIG. 1. In FIG. 3, an organic light-emitting diode OLED that is the display element DPE is electrically connected to the pixel circuit PC. In detail, a pixel electrode of the organic light-emitting diode OLED may be electrically connected to the pixel circuit PC, and a counter electrode of the organic light-emitting diode OLED may be electrically connected to a common voltage line ESL through which a common power voltage ELVSS is provided. The organic light-emitting diode OLED may emit light with a luminance corresponding to the amount of a current provided from the pixel circuit PC.

The pixel circuit PC may include a first transistor T1, a second transistor T2, a third transistor T3, and a storage capacitor Cst. Each of the first transistor T1, the second transistor T2, and the third transistor T3 may be an oxide semiconductor thin film transistor including a semiconductor layer consisting of an oxide semiconductor, or a silicon semiconductor thin film transistor including a semiconductor layer consisting of polysilicon.

The first transistor T1 may be a driving transistor. One end of the first transistor T1 may be electrically connected to the pixel electrode of the organic light-emitting diode OLED, and the other end of the first transistor T1 may be electrically connected to a power line EDL through which a driving power voltage ELVDD is provided. A driving gate electrode of the first transistor T1 may be electrically connected to a first node N1. The first transistor T1 may control the amount of a current flowing from the power line EDL to the organic light-emitting diode OLED corresponding to a voltage of the first node N1.

The second transistor T2 may be a switching transistor. One end of the second transistor T2 may be electrically connected to a data line DL, and the other end of the second transistor T2 may be electrically connected to the first node N1. A switching gate electrode of the second transistor T2 may be electrically connected to a scan line SL. The second transistor T2 may be turned on if a scan signal SS is provided through the scan line SL to electrically connect the data line DL to the first node N1, so that a data signal DATA from the data line DL may be transmitted to the first node N1.

The third transistor T3 may be an initialization-sensing transistor. One end of the third transistor T3 may be electrically connected to an initialization-sensing line ISL, and the other end of the third transistor T3 may be electrically connected to a second node N2. An initialization gate electrode of the third transistor T3 may be electrically connected to a control line CL.

The third transistor T3 may be turned on if a control signal CS is provided through the control line CL to electrically connect the initialization-sensing line ISL to the second node N2, so that an initialization-sensing signal ISS from the initialization-sensing line ISL may be transmitted to the second node N2. For example, if turned on, the third transistor T3 may initialize the electric potential of the pixel electrode of the organic light-emitting diode OLED, by using the initialization-sensing signal ISS through the initialization-sensing line ISL, as an initialization voltage. Alternatively, if turned on, the third transistor T3 may sense information about the characteristics of the organic light-emitting diode OLED. As such, the third transistor T3 may include both or any one of a function as an initialization transistor and a function as a sensing transistor. If the third transistor T3 has a function as an initialization transistor, the initialization-sensing line ISL may be regarded as an initialization voltage line, and if the third transistor T3 has a function as a sensing transistor, the initialization-sensing line ISL may be regarded as a sensing line. The initialization operation and the sensing operation of the third transistor T3 may be individually or concurrently/substantially simultaneously performed. In other words, the third transistor T3 may be an initialization transistor and/or a sensing transistor. In the following description, for convenience of explanation, a case in which the third transistor T3 has both of the function as an initialization transistor and the function as a sensing transistor is mainly described.

The storage capacitor Cst may be connected between the first node N1 and the second node N2. For example, one capacitor electrode of the storage capacitor Cst may be electrically connected to the gate electrode of the first transistor T1, and the other capacitor electrode of the storage capacitor Cst may be electrically connected to the pixel electrode of the organic light-emitting diode OLED.

Although FIG. 3 illustrates that the pixel circuit PC includes three transistors T1, T2, and T3 and one storage capacitor Cst, the disclosure is not limited thereto. For example, the number of transistors and storage capacitors included in the pixel circuit PC may vary.

Although FIG. 3 illustrates that the display element DPE is the organic light-emitting diode OLED including an organic material, the disclosure is not limited thereto. For example, the display element DPE may be an inorganic light-emitting diode including an inorganic material. The inorganic light-emitting diode may include a PN diode including materials based on an inorganic material semiconductor. If a voltage is applied to a PN junction diode in a forward direction, holes and electrons are injected, and thus, light of a corresponding color may be emitted by converting energy generated by the recombination of the holes and the electrons into light energy. The inorganic light-emitting diode may have a width of several to hundreds of micrometers. The inorganic light-emitting diode may be referred to as a micro light-emitting diode (LED).

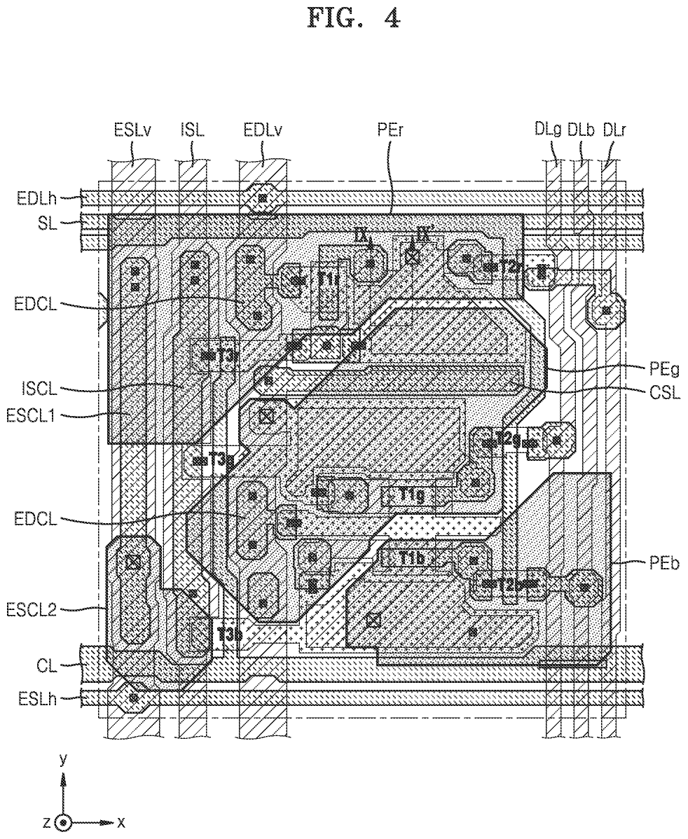

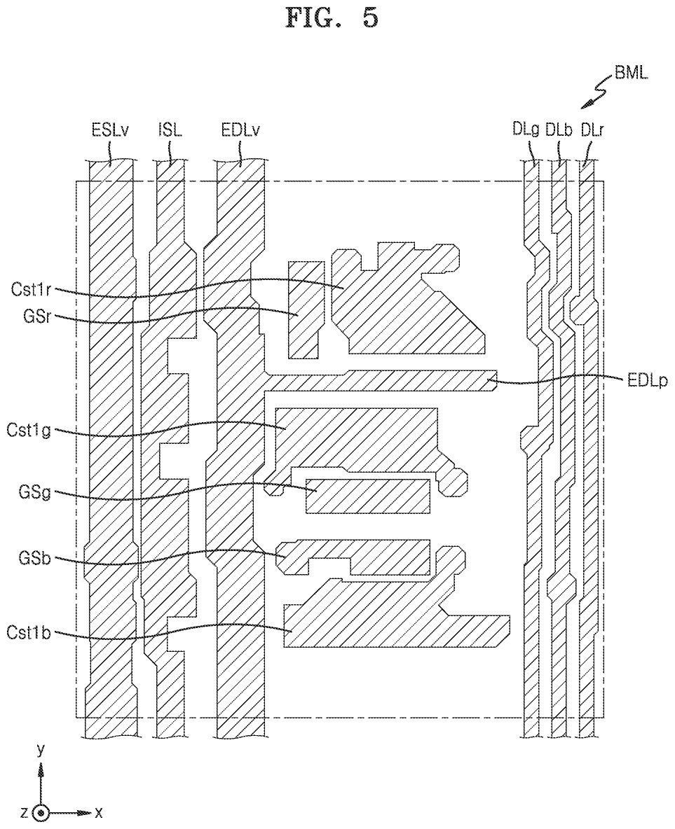

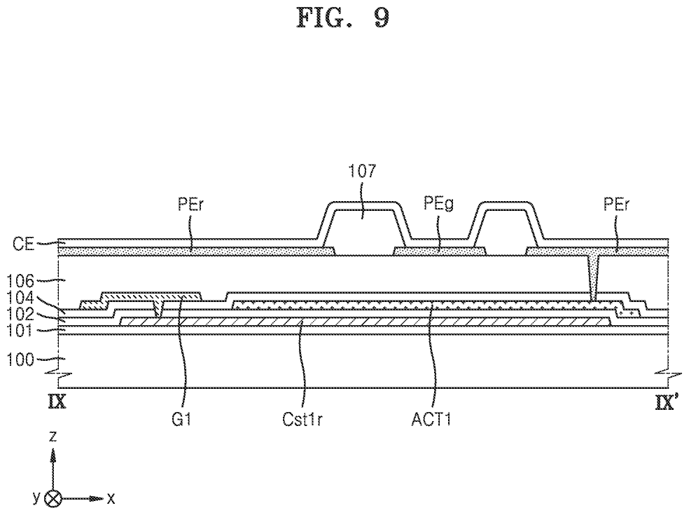

FIG. 4 is a schematic layout diagram showing the locations of the transistors T1, T2, and T3 and the storage capacitor Cst in one pixel in the display apparatus 1 of FIG. 1. FIGS. 5 to 8 are layout diagrams schematically showing, by layer, constituent elements, such as the transistors T1, T2, and T3, the storage capacitor Cst, and the like, of the display apparatus 1 illustrated in FIG. 4. FIG. 9 is a schematic cross-sectional view taken along the line IX-IX′ of FIG. 4. For reference, as one pixel may include a plurality of sub-pixels, for example, three sub-pixels, the equivalent circuit diagram of FIG. 3 described above may be an equivalent circuit diagram of one sub-pixel. FIG. 4 schematically illustrates the locations of the transistors T1, T2, and T3, the storage capacitor Cst, and the like in one pixel including three sub-pixels.

Referring to FIGS. 4 to 9, one pixel may include three sub-pixels. In other words, one pixel may include a first sub-pixel Pr, a second sub-pixel Pg, and a third sub-pixel Pb. The first sub-pixel Pr, as a sub-pixel in an area where red light is emitted, may be referred to as a red sub-pixel. The second sub-pixel Pg, as a sub-pixel in an area where green light is emitted, may be referred to as a green sub-pixel. The third sub-pixel Pb, as a sub-pixel in an area where blue light is emitted, may be referred to as a blue sub-pixel. The first sub-pixel Pr, the second sub-pixel Pg, and the third sub-pixel Pb may each include one storage capacitor Cst including a first capacitor electrode Cst1 (see FIG. 5), and the three transistors T1, T2, and T3. The constituent elements of the second sub-pixel Pg and the constituent elements of the third sub-pixel Pb are the same as and/or similar to the constituent elements of the first sub-pixel Pr. Accordingly, in the following description, for convenience of explanation, the constituent elements of the first sub-pixel Pr are mainly described, and the description may be also applied to the constituent elements of the second sub-pixel Pg and the constituent elements of the third sub-pixel Pb.

The display apparatus 1 may include a substrate 100 (see FIG. 9), and various constituent elements, such as transistors T1r, T2r, and T3r, the storage capacitor Cst, and the like, of the first sub-pixel Pr may be located on substrate 100. The substrate 100 may include glass, metal, or polymer resin. If the substrate 100 is flexible or bendable, the substrate 100 may include polymer resin, for example, polyethersulfone, polyacrylate, polyetherimide, polyethylene naphthalate, polyethylene terephthalate, polyphenylene sulfide, polyarylate, polyimide, polycarbonate, or cellulose acetate propionate. The substrate 100 may be variously modified. For example, the substrate 100 may have a multilayer structure of two layers including the polymer resin described above and an inorganic material, such as a silicon oxide, a silicon nitride, a silicon oxynitride, and the like, provided therebetween.

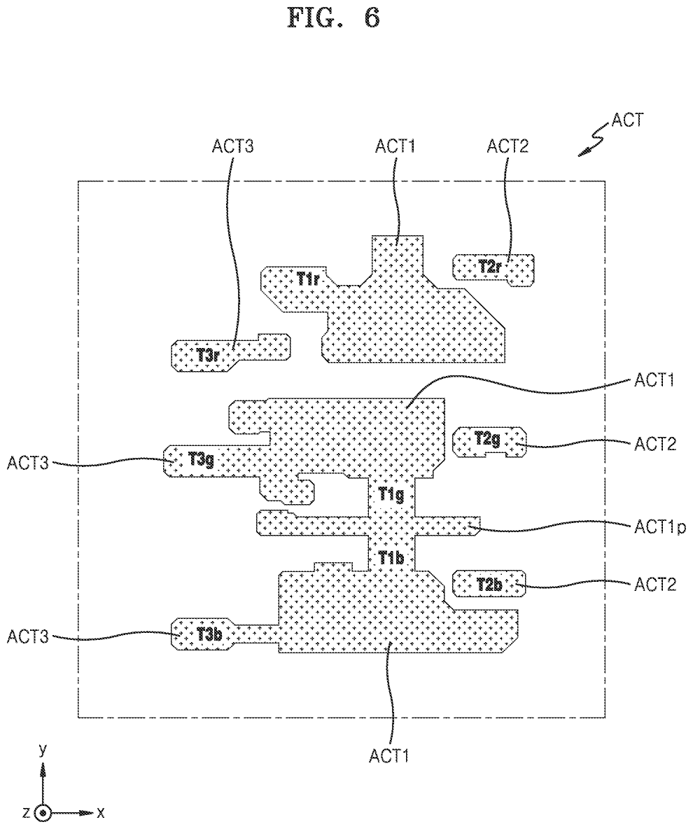

A first buffer layer 101 (see FIG. 9) including an inorganic insulating material, such as a silicon oxide, a silicon nitride, a silicon oxynitride, an aluminum oxide, and/or the like, may be located on the substrate 100. The first buffer layer 101 may reduce or prevent a phenomenon in which metal atoms, impurities, or the like from the substrate 100 are diffused into an active layer ACT (see FIG. 6) located thereabove.

A bottom metal layer BML as illustrated in FIG. 5 may be located on the first buffer layer 101. The bottom metal layer BML may include various signal lines, and may serve to protect an active layer ACT located thereabove by overlapping at least a portion of the active layer ACT. If the active layer ACT includes polysilicon, the bottom metal layer BML may facilitate uniform crystallization of the active layer ACT by adjusting a rate at which heat is provided during a crystallization process for forming the active layer ACT. The bottom metal layer BML may include a metal, an alloy, a conductive metal oxide, a transparent conductive material, or the like. For example, the bottom metal layer BML may include silver (Ag), an alloy containing Ag, molybdenum (Mo), an alloy containing Mo, aluminum (Al), an alloy containing Al, an aluminum nitride (AlN), tungsten (W), a tungsten nitride (WN), copper (Cu), nickel (Ni), chromium (Cr), a chromium nitride (CrN), titanium (Ti), tantalum (Ta), platinum (Pt), scandium (Sc), an indium tin oxide (ITO), an indium zinc oxide (IZO), or the like. The bottom metal layer BML may have a multilayer structure, for example, a two-layer structure of Mo/Al or Ti/Al or a three-layer structure of Mo/Al/Mo or Ti/Al/Ti.

As illustrated in FIG. 5, the bottom metal layer BML may include a vertical common voltage line ESLv, the initialization-sensing line ISL, a vertical power line EDLv, a first data line DLr, a second data line DLg, a third data line DLb, first capacitor electrodes Cst1r, Cst1g, and Cst1b, and driving gate shields GSr, GSg, and GSb. The vertical common voltage line ESLv, the initialization-sensing line ISL, the vertical power line EDLv, the second data line DLg, the third data line DLb, and the first data line DLr may be sequentially arranged in a first direction (x-axis direction).

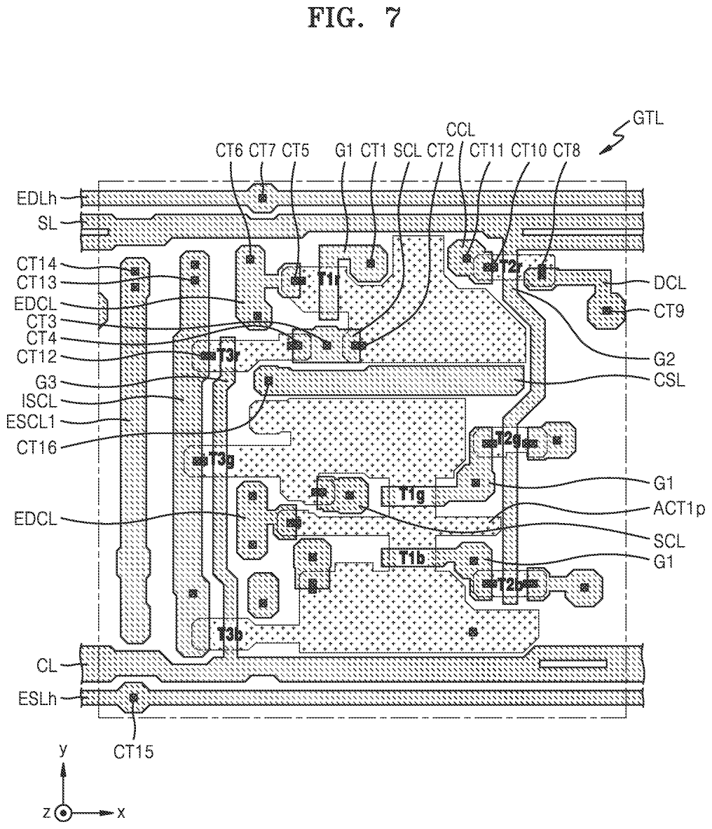

The vertical common voltage line ESLv may extend in a second direction (y-axis direction) crossing the first direction (x-axis direction). The vertical common voltage line ESLv may be electrically connected to a horizontal common voltage line ESLh (see FIG. 7) extending in the first direction (x-axis direction) and described below. Accordingly, the common voltage line ESL including the vertical common voltage line ESLv and the horizontal common voltage line ESLh, which are mutually electrically connected to each other, may have an approximate grid shape in the display area DA. Accordingly, in the display area DA, the common voltage line ESL may have an electric potential corresponding to the common power voltage ELVSS that is approximately uniform. The common voltage line ESL may be electrically connected to a common electrode CE (see FIG. 9) that is an upper electrode of the organic light-emitting diode OLED, so that in the display area DA, the common electrode CE may have a uniform electric potential.

The initialization-sensing line ISL may extend in the second direction (y-axis direction). The initialization-sensing line ISL may be electrically connected to each of third transistors T3r, T3g, and T3b that are initialization-sensing transistors, and if the third transistors T3r, T3g, and T3b are turned on, the initialization-sensing signal ISS through the initialization-sensing line ISL may be transmitted to a first pixel electrode PEr, a second pixel electrode PEg, or a third pixel electrode PEb.

The vertical power line EDLv may extend in the second direction (y-axis direction). The vertical power line EDLv may be electrically connected to a horizontal power line EDLh (see FIG. 7) extending in the first direction (x-axis direction) and described below. Accordingly, the power line EDL including the vertical power line EDLv and the horizontal power line EDLh, which are mutually and electrically connected to each other may have an approximate grid shape in the display area DA. Accordingly, in the display area DA, the power line EDL may have an electric potential of a power voltage ELVDD that is approximately uniform. The power line EDL may be electrically connected to each of the first transistors T1r, T1g, and T1b that are driving transistors, and may serve to apply the power voltage ELVDD to the first transistors T1r, T1g, and T1b.

Furthermore, the vertical power line EDLv may further include a protruding portion EDLp. The protruding portion EDLp may extend in the first direction (x-axis direction), that is, in a horizontal direction that is perpendicular to an extension direction of the vertical power line EDLv.

In one or more embodiments, the protruding portion EDLp may cross between two adjacent electrodes of the first capacitor electrodes Cst1r, Cst1g, and Cst1b. For example, the protruding portion EDLp may cross between the first capacitor electrode Cst1r of the first sub-pixel Pr and the first capacitor electrode Cst1g of the second sub-pixel Pg. The protruding portion EDLp may extend adjacent to an electrode for forming switching gate electrodes of sub-pixels, toward the second data line DLg. Accordingly, the opposite ends of the protruding portion EDLp in the first direction (x-axis direction) may extend beyond the opposite ends of the first capacitor electrode Cst1r of the first sub-pixel Pr in the first direction (x-axis direction). Furthermore, the opposite ends of the protruding portion EDLp in the first direction (x-axis direction) may extend beyond the opposite ends of the first capacitor electrode Cst1g of the second sub-pixel Pg in the first direction (x-axis direction). In this case, the protruding portion EDLp of the vertical power line EDLv may be electrically connected to a capacitor-blocking line CSL to be described below, and may shield (with the capacitor-blocking line CSL) an electromagnetic field between the storage capacitor Cst of the first sub-pixel Pr and the storage capacitor Cst of the second sub-pixel Pg. This will be described below.

The second data line DLg, the third data line DLb, and the first data line DLr may each extend in the second direction (y-axis direction). The first data line DLr, as a red data line, may be electrically connected to the second transistor T2r of the first sub-pixel Pr. The second data line DLg, as a green data line, may be electrically connected to the second transistor T2g of the second sub-pixel Pg. The third data line DLb, as a blue data line, may be electrically connected to the second transistor T2b of the third sub-pixel Pb. If the second transistor T2r of the first sub-pixel Pr, the second transistor T2g of the second sub-pixel Pg, and the second transistor T2b of the third sub-pixel Pb are turned on in response to the scan signal SS through the scan line SL (see FIG. 7), the second transistor T2r of the first sub-pixel Pr, the second transistor T2g of the second sub-pixel Pg, and the second transistor T2b of the third sub-pixel Pb may transmit the data signal DATA from the first data line DLr, the second data line DLg, and the third data line DLb to a driving gate electrode of the first transistor Tir of the first sub-pixel Pr, a driving gate electrode of the first transistor T1g of the second sub-pixel Pg, and a driving gate electrode of the first transistor T1b of the third sub-pixel Pb.

The first capacitor electrodes Cst1r, Cst1g, and Cst1b and the driving gate electrode shields GSr, GSg, and GSb may be located between a set of the vertical common voltage line ESLv, the initialization-sensing line ISL, and the vertical power line EDLv, and a set of the second data line DLg, the third data line DLb, and the first data line DLr. If viewed from a direction (z-axis direction) perpendicular to the substrate 100 (e.g., in a plan view), each of the first capacitor electrodes Cst1r, Cst1g, and Cst1b and each of the driving gate electrode shields GSr, GSg, and GSb may have an isolated shape.

The first capacitor electrodes Cst1r, Cst1g, and Cst1b may each be a capacitor electrode of the storage capacitor Cst. The driving gate electrode shields GSr, GSg, and GSb may each overlap at least a portion of the driving gate electrode, and may serve to protect the active layer ACT located thereabove.

A second buffer layer 102 (see FIG. 9) may be located on the first buffer layer 101 to cover the bottom metal layer BML. The second buffer layer 102 may include an insulating material. For example, the second buffer layer 102 may include an inorganic insulating material, such as a silicon oxide, a silicon nitride, a silicon oxynitride, an aluminum oxide, or the like.

The active layer ACT as illustrated in FIG. 6 may be located on the second buffer layer 102. The active layer ACT may include polysilicon or an oxide semiconductor. The oxide semiconductor may include a Zn oxide, an In—Zn oxide, or a Ga—In—Zn oxide as a Zn oxide-based material. Alternatively, oxide semiconductor may include In—Ga—Zn—O (IGZO), In—Sn—Zn—O (ITZO), or In—Ga—Sn—Zn—O (IGTZO), in which a metal, such as indium (In), gallium (Ga), or tin (Sn,) is contained in a zinc oxide (ZnO). In the following description, for convenience of explanation, a case in which the active layer ACT includes an oxide semiconductor is described.

The active layer ACT may include a first active layer ACT1, a second active layer ACT2, and a third active layer ACT3. With respect to the active layer ACT of the first sub-pixel Pr, the first active layer ACT1 may be a constituent element of the first transistor T1r. The first transistor T1r may be a driving transistor. The first active layer ACT1 may also overlap the first capacitor electrode Cst1r of the storage capacitor Cst, and may serve as a second capacitor electrode. The second active layer ACT2 may be a constituent element of the second transistor T2r. The second transistor T2r may be a switching transistor. The third active layer ACT3 may be a constituent element of the third transistor T3r. The third transistor T3r may be an initialization-sensing transistor.

The first active layer ACT1, the second active layer ACT2, and the third active layer ACT3 may be separately and individually formed, but the disclosure is not limited thereto. In one or more embodiments, as shown in the active layer ACT of the second sub-pixel Pg and the third sub-pixel Pb, the first active layer ACT1 and the third active layer ACT3 may be integrally formed.

A gate-insulating layer 104 (see FIG. 9) may be located on the second buffer layer 102 to cover the active layer ACT. The gate-insulating layer 104 may include an insulating material. For example, the gate-insulating layer 104 may include an inorganic insulating material, such as a silicon oxide, a silicon nitride, a silicon oxynitride, an aluminum oxide, or the like.

A gate layer GTL, as shown in FIG. 7, may be located on the gate-insulating layer 104 (see FIG. 9). For reference, for convenience of explanation, FIG. 7 illustrates the gate layer GTL with the active layer ACT.

The gate layer GTL may include the horizontal common voltage line ESLh, the scan line SL, the control line CL, and the horizontal power line EDLh, which extend approximately in the first direction (x-axis direction), a first common voltage connection line ESCL1 and an initialization-sensing connection line ISCL, which extend approximately in the second direction (y-axis direction), and a data connection line DCL, a capacitor connection line CCL, a shield connection line SCL, a first gate electrode G1, a power connection line EDCL, and the capacitor-blocking line CSL, which have isolated shapes. In one or more embodiments, each of the first sub-pixel Pr, the second sub-pixel Pg, and the third sub-pixel Pb may include the data connection line DCL, the capacitor connection line CCL, the shield connection line SCL, the first gate electrode G1, the power connection line EDCL, and the capacitor-blocking line CSL. In this case, the second sub-pixel Pg and the third sub-pixel Pb may each be arranged in a pattern similar to an arrangement pattern of the bottom metal layer BML, the active layer ACT, and the gate layer GTL of the first sub-pixel Pr. In one or more other embodiments, the second sub-pixel Pg and the third sub-pixel Pb, as illustrated in FIGS. 4 to 8, may not include the capacitor connection line CCL and the capacitor-blocking line CSL. In this case, the first active layer ACT1 of the second sub-pixel Pg and the first active layer ACT1 of the third sub-pixel Pb may serve as the capacitor-blocking line CSL. In the following description, to describe various embodiments, as illustrated in FIGS. 4 to 8, a case in which the arrangement pattern of the second sub-pixel Pg and the third sub-pixel Pb is slightly different from the arrangement pattern of the first sub-pixel Pr is mainly described.

The gate layer GTL may include a metal, an alloy, a conductive metal oxide, a transparent conductive material, or the like. For example, the gate layer GTL may include Ag, an alloy containing Ag, Mo, an alloy containing Mo, Al, an alloy containing Al, AlN, W, WN, Cu, Ni, Cr, CrN, Ti, Ta, Pt, Sc, ITO, IZO, or the like. The gate layer GTL may have a multilayer structure, for example, the gate layer GTL may have a two-layer structure of Mo/Al or Ti/Al, or may have a three-layer structure of Mo/Al/Mo or Ti/Al/Ti.

As described above, although FIG. 7 illustrates, for convenience of explanation, the gate layer GTL with the active layer ACT, impurities may be added in a portion of the gate layer GTL that does not overlap the active layer ACT. In other words, the portion of the gate layer GTL that does not overlap the active layer ACT may be a doped portion. Accordingly, the electrical characteristics of the portion of the gate layer GTL that does not overlap the active layer ACT may be different from the electrical characteristics of a portion of the gate layer GTL that overlaps the active layer ACT. In detail, the resistance of the portion of the gate layer GTL that does not overlap the active layer ACT may be less than the resistance of the portion of the gate layer GTL that overlaps the active layer ACT if no channel is formed in the portion. Accordingly, for example, in the first sub-pixel Pr, a portion of the first active layer ACT1 that overlaps the first capacitor electrode Cst1r may function as a conductor so as to be a second capacitor electrode. Furthermore, the portion of the gate layer GTL that does not overlap the active layer ACT may be a source region or a drain region and may also serve as a wire.

In an example of the first sub-pixel Pr, the first transistor T1r may include the first gate electrode G1 and the first active layer ACT1. The first gate electrode G1 may be a driving gate electrode. Similarly, the second transistor T2r may include a second gate electrode G2 and the second active layer ACT2. The second gate electrode G2 may be a switching gate electrode. The third transistor T3r may include a third gate electrode G3 and the third active layer ACT3. The third gate electrode G3 may be an initialization-sensing gate electrode.

The first active layer ACT1, the second active layer ACT2, and the third active layer ACT3 may partially overlap the first gate electrode G1, the second gate electrode G2, and the third gate electrode G3, respectively, and each overlapping portion of the active layer may be defined as a channel portion. The first active layer ACT1, the second active layer ACT2, and the third active layer ACT3 may each include a first part and a second part that are respectively located at one side and the other side of the channel portion.

The first gate electrode G1 may be electrically connected to the first capacitor electrode Cst1r through a first contact hole CT1.

The first part of the first active layer ACT1 may be electrically connected to the shield connection line SCL thereabove through a second contact hole CT2. The shield connection line SCL may be electrically connected to the driving gate electrode shield GSr thereunder through a third contact hole CT3, and may be electrically connected to the first part of the third active layer ACT3 thereunder through a fourth contact hole CT4. The first part of the first active layer ACT1 may be located above the first capacitor electrode Cst1r to overlap the first capacitor electrode Cst1r, and may serve as a second capacitor electrode as described above. As such, as the first capacitor electrode Cst1r of the bottom metal layer BML corresponds to the first part of the first active layer ACT1 of the active layer ACT to form the storage capacitor Cst, as described below, the second pixel electrode PEg of the second sub-pixel Pg may be located above the storage capacitor Cst of the first sub-pixel Pr to overlap the same. In detail, a coupling gap between the gate electric potential of the driving transistor of the first sub-pixel Pr and the electric potential of the second pixel electrode PEg may generate a color step. Accordingly, in general, the second pixel electrode PEg may not be located above the first sub-pixel Pr. According to one or more embodiments, as an upper portion of the first capacitor electrode Cst1r, which is electrically connected to the driving gate electrode, is covered by the first part of the first active layer ACT1, which is electrically connected to the first pixel electrode PEr, the electric potential of the driving gate of the first sub-pixel Pr may be shielded. Accordingly, the second pixel electrode PEg may be located above the first sub-pixel Pr, for example, the storage capacitor Cst.

The second part of the first active layer ACT1 may be electrically connected to the power connection line EDCL thereabove through a fifth contact hole CT5. The power connection line EDCL may be electrically connected to the vertical power line EDLv thereunder through a sixth contact hole CT6. The vertical power line EDLv may be electrically connected to the horizontal power line EDLh thereabove through a seventh contact hole CT7.

The second gate electrode G2 may be electrically connected to the scan line SL to constitute a portion of the scan line SL. In detail, the scan line SL may extend approximately in the first direction (x-axis direction), and may have a protruding portion protruding in the second direction (y-axis direction). The protruding portion of the scan line SL may extend toward the third sub-pixel Pb by crossing the first sub-pixel Pr and the second sub-pixel Pg. The protruding portion of the scan line SL may be used as the second gate electrode G2 of each of the first sub-pixel Pr, the second sub-pixel Pg, and the third sub-pixel Pb. In other words, the second gate electrode G2 of each of the first sub-pixel Pr, the second sub-pixel Pg, and the third sub-pixel Pb may be integrally formed.

The first part of the second active layer ACT2 may be electrically connected to the data connection line DCL thereabove through an eighth contact hole CT8. The data connection line DCL may be electrically connected to the first data line DLr thereunder through a ninth contact hole CT9.

The second part of the second active layer ACT2 may be electrically connected to the capacitor connection line CCL thereabove through a tenth contact hole CT10. The capacitor connection line CCL may be electrically connected to the first capacitor electrode Cst1r thereunder through an eleventh contact hole CT11.

The third gate electrode G3 may be electrically connected to the control line CL to constitute a portion of the control line CL. In detail, the control line CL may extend approximately in the first direction (x-axis direction), and may include a protruding portion that protrudes in the second direction (y-axis direction). The protruding portion of the control line CL may extend toward the first sub-pixel Pr to extend past the third sub-pixel Pb and the second sub-pixel Pg. The protruding portion of the control line CL may be used as the third gate electrode G3 of each of the first sub-pixel Pr, the second sub-pixel Pg, and the third sub-pixel Pb. In other words, the third gate electrode G3 of each of the first sub-pixel Pr, the second sub-pixel Pg, and the third sub-pixel Pb may be integrally formed.

The first part of the third active layer ACT3 may be electrically connected to the shield connection line SCL thereabove through the fourth contact hole CT4, as described above.

The second part of the third active layer ACT3 may be electrically connected to the initialization-sensing connection line ISCL thereabove through a twelfth contact hole CT12. The initialization-sensing connection line ISCL may be electrically connected to the initialization-sensing line ISL thereunder through a thirteenth contact hole CT13.

The first common voltage connection line ESCL1 may be electrically connected to the vertical common voltage line ESLv thereunder through a fourteenth contact hole CT14. However, the horizontal common voltage line ESLh may be electrically connected to the vertical common voltage line ESLv thereunder through a fifteenth contact hole CT15.

The capacitor-blocking line CSL may be electrically connected to the vertical power line EDLv thereunder through a sixteenth contact hole CT16. In one or more embodiments, the capacitor-blocking line CSL may be larger than the protruding portion EDLp to overlap the protruding portion EDLp of the vertical power line EDLv, in a plan view. Furthermore, the capacitor-blocking line CSL may cross between two adjacent electrodes of the first capacitor electrodes Cst1r, Cst1g, and Cst1b. For example, the capacitor-blocking line CSL may cross between the first capacitor electrode Cst1r of the first sub-pixel Pr and the first capacitor electrode Cst1g of the second sub-pixel Pg. The capacitor-blocking line CSL may extend toward the second data line DLg to be adjacent to the electrodes constituting the switching gate electrodes of the sub-pixels, that is, the protruding portion of the scan line SL. Accordingly, the opposite ends of the capacitor-blocking line CSL in the first direction (x-axis direction) may extend beyond the opposite ends of the first capacitor electrode Cst1r of the first sub-pixel Pr in the first direction (x-axis direction). Furthermore, the opposite ends of the capacitor-blocking line CSL in the first direction (x-axis direction) may extend beyond the opposite ends of the first capacitor electrode Cst1g of the second sub-pixel Pg in the first direction (x-axis direction).

The capacitor-blocking line CSL may shield, with the protruding portion EDLp of the vertical power line EDLv, an electromagnetic field between the storage capacitor Cst of the first sub-pixel Pr and the storage capacitor Cst of the second sub-pixel Pg. In detail, as the capacitor-blocking line CSL and the protruding portion EDLp are both electrically connected to the vertical power line EDLv, the driving power voltage ELVDD may be provided thereto. Accordingly, the coupling between the storage capacitor Cst of the first sub-pixel Pr and the storage capacitor Cst of the second sub-pixel Pg may be reduced or prevented. As such, as the coupling between the storage capacitors Cst is reduced or prevented, a problem of noise generation or energy loss may be reduced or prevented.

In this state, the protruding portion EDLp of the vertical power line EDLv may be electrically connected to the capacitor-blocking line CSL to be described below, and may shield, with the capacitor-blocking line CSL, an electromagnetic field between the storage capacitor Cst of the first sub-pixel Pr and the storage capacitor Cst of the second sub-pixel Pg.

A difference in the first sub-pixel Pr from the arrangement pattern of the second sub-pixel Pg and the third sub-pixel Pb is mainly described.

The first gate electrode G1 of the second sub-pixel Pg and the first gate electrode G1 of the third sub-pixel Pb may face each other, in a plan view. In other words, unlike the first gate electrode G1 of the first sub-pixel Pr, which is arranged in one side of the first capacitor electrode Cst1r in the first direction (x-axis direction), in one or more embodiments, the first gate electrode G1 of the second sub-pixel Pg and the first gate electrode G1 of the third sub-pixel Pb may be respectively arranged in one side of the first capacitor electrodes Cst1g and Cst1b in the second direction (y-axis direction). For example, the first gate electrode G1 of the second sub-pixel Pg may be arranged under the first capacitor electrode Cst1g. The first gate electrode G1 of the third sub-pixel Pb may be located above the first capacitor electrode Cst1b.

Furthermore, the first gate electrode G1 of the second sub-pixel Pg and the first gate electrode G1 of the third sub-pixel Pb may be integrally formed with the capacitor connection line CCL. In other words, the first gate electrode G1 of the second sub-pixel Pg and the first gate electrode G1 of the third sub-pixel Pb may be electrically connected to the first capacitor electrodes Cst1g and Cst1b, and may be electrically connected to the second part of the second active layer ACT2.

Furthermore, in each of the second sub-pixel Pg and the third sub-pixel Pb, the first active layer ACT1 and the third active layer ACT3 may be connected to each other. For example, the first part of the first active layer ACT1 and the first part of the third active layer ACT3 may be connected to each other. In other words, in each of the second sub-pixel Pg and the third sub-pixel Pb, the first active layer ACT1 and the third active layer ACT3 may be integrally formed.

Furthermore, in the second sub-pixel Pg, the second part of the first active layer ACT1 may cross between two adjacent electrodes of the first capacitor electrodes Cst1r, Cst1g, and Cst1b. For example, the second part of the first active layer ACT1 may cross between the first capacitor electrode Cst1g of the second sub-pixel Pg and the first capacitor electrode Cst1b of the third sub-pixel Pb. The second part of the first active layer ACT1 may have a protruding portion ACT1p, and the protruding portion ACT1p may extend toward the second data line DLg to be adjacent to the electrodes constituting the second gate electrodes of the sub-pixels, that is, the protruding portion of the scan line SL. Accordingly, the opposite ends of the second part of the first active layer ACT1 in the first direction (x-axis direction) may extend beyond the opposite ends of the first capacitor electrode Cst1g of the second sub-pixel Pg in the first direction (x-axis direction). In this case, similarly to the capacitor-blocking line CSL described above, the protruding portion ACT1p may shield an electromagnetic field between the storage capacitor Cst of the second sub-pixel Pg and the storage capacitor Cst of the third sub-pixel Pb. In detail, as the second part of the first active layer ACT1 is electrically connected to the vertical power line EDLv through the power connection line EDCL, the driving power voltage ELVDD may be provided to the first active layer ACT1. Accordingly, the coupling between the storage capacitor Cst of the second sub-pixel Pg and the storage capacitor Cst of the third sub-pixel Pb may be reduced or prevented.

In one or more embodiments, to shield a field between the storage capacitors Cst of the respective sub-pixels, the capacitor-blocking line CSL may be used, the second part of the first active layer ACT1 having the protruding portion ACT1p, or both of them may be used.

Furthermore, it can be said that the first active layer ACT1 of the third sub-pixel Pb is connected to the first active layer ACT1 of the second sub-pixel Pg. For example, the second part of the first active layer ACT1 of the third sub-pixel Pb and the second part of the first active layer ACT1 of the second sub-pixel Pg may be shared. Accordingly, the power connection line EDCL of the second sub-pixel Pg and the power connection line EDCL of the third sub-pixel Pb may be shared. In other words, the power connection line EDCL of the second sub-pixel Pg and the power connection line EDCL of the third sub-pixel Pb may be integrally formed.

A planarization layer 106 may cover the gate layer GTL, and may be located on the gate layer GTL. The planarization layer 106 may include an organic insulating material. For example, the planarization layer 106 may include photoresist, benzocyclobutene (BCB), polyimide, hexamethyldisiloxane (HMDSO), polymethylmethacrylate (PMMA), polystyrene, a polymer derivative having a phenolic group, an acrylic polymer, an imide-based polymer, an aryl ether-based polymer, an amide-based polymer, a fluorine-based polymer, a p-xylene-based polymer, a vinyl alcohol-based polymer, a mixture thereof, and/or the like.

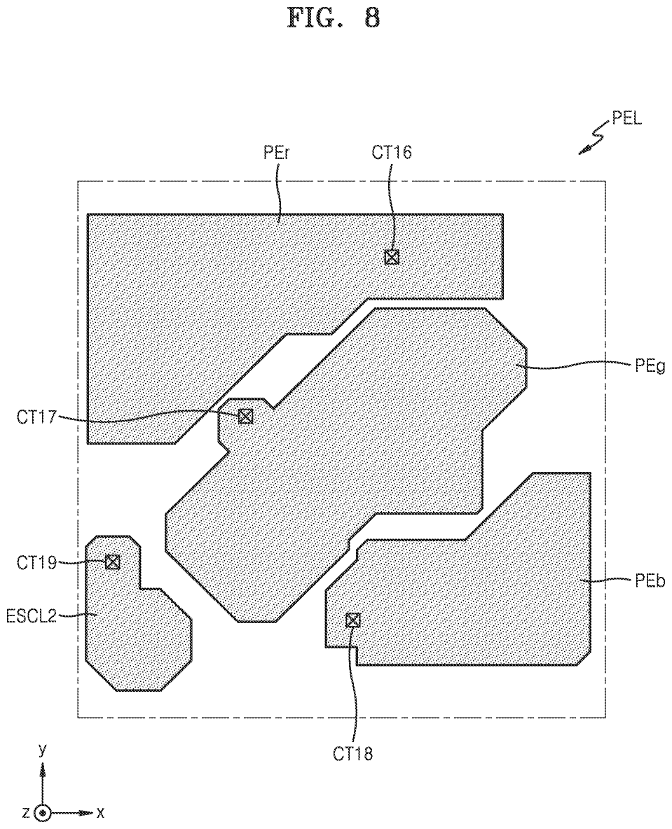

As illustrated in FIG. 8, a pixel electrode layer PEL may be located on the planarization layer 106. The pixel electrode layer PEL may include the first pixel electrode PEr, the second pixel electrode PEg, the third pixel electrode PEb, and a second common voltage connection line ESCL2. The pixel electrode layer PEL may be a (semi-)light-transmissive electrode layer or a reflective electrode layer. For example, the pixel electrode layer PEL may include a reflective layer including Ag, Mg, Al, Pt, Pd, Au, Ni, Nd, Ir, Cr, a compound thereof, and/or the like, and a transparent or semi-transparent electrode layer located on the reflective layer. The transparent or semi-transparent electrode layer may include at least one selected from among an indium tin oxide (ITO), an indium zinc oxide (IZO), a zinc oxide (ZnO), an indium oxide (In₂O₃), an indium gallium oxide (IGO), and/or an aluminum zinc oxide (AZO). For example, the pixel electrode layer PEL may have a three-layer structure of ITO/Ag/ITO.

The first pixel electrode PEr, as a pixel electrode in an area where red light is emitted, may be referred to as a red pixel electrode. The second pixel electrode PEg, as a pixel electrode in an area where green light is emitted, may be referred to as a green pixel electrode. The third pixel electrode PEb, as a pixel electrode in an area where blue light is emitted, may be referred to as a blue pixel electrode.

The first pixel electrode PEr may be connected to the first sub-pixel Pr, and in detail, may be electrically connected to the first active layer ACT1 of the first sub-pixel Pr thereunder through the sixteenth contact hole CT16. The second pixel electrode PEg may be connected to the second sub-pixel Pg, and in detail, may be connected to the first active layer ACT1 of the second sub-pixel Pg thereunder through a seventeenth contact hole CT17. The third pixel electrode PEb may be connected to the third sub-pixel Pb, and in detail, may be connected to the first active layer ACT1 of the third sub-pixel Pb thereunder through an eighteenth contact hole CT18.

A pixel-defining layer 107 may be located on the planarization layer 106. The pixel-defining layer 107 may have openings to expose central portions of the first pixel electrode PEr, the second pixel electrode PEg, and the third pixel electrode PEb, and may cover edges of the first pixel electrode PEr, the second pixel electrode PEg, and the third pixel electrode PEb. Accordingly, the pixel-defining layer 107 may increase a distance between the edge of each of the first pixel electrode PEr, the second pixel electrode PEg, and the third pixel electrode PEb and the common electrode CE thereabove, and may serve to reduce or prevent the likelihood of generation of an arc and the like in the edges of the first pixel electrode PEr, the second pixel electrode PEg, and the third pixel electrode PEb. Furthermore, the pixel-defining layer 107 may expose at least a portion of the second common voltage connection line ESCL2 to bring the common electrode CE into contact with the second common voltage connection line ESCL2. As the second common voltage connection line ESCL2 is electrically connected to the first common voltage connection line ESCL1 thereunder through a nineteenth contact hole CT19, the common electrode CE may be electrically connected to the common voltage line ESL including the vertical common voltage line ESLv and the horizontal common voltage line ESLh, through the second common voltage connection line ESCL2 and the first common voltage connection line ESCL1. The pixel-defining layer 107 may include one or more organic insulating materials selected from among polyimide, polyamide, acryl resin, benzocyclobutene, and phenol resin, and may be formed by a method, such as spin coating and the like.

The common electrode CE may be a light-transmissive electrode or reflective electrode. For example, the common electrode CE may be a transparent or semi-transparent electrode, and may include a metal thin film having a relatively low work function including Li, Ca, LiF, Al, Ag, Mg, and a compound thereof. Furthermore, the common electrode CE may further include a transparent conductive oxide (TCO) film located above the metal thin film and including ITO, IZO, ZnO, In₂O₃, or the like. The common electrode CE may be integrally formed on the entire surface of the display area DA, and may be located above a plurality of pixel electrodes.

An intermediate layer may be located between the pixel electrodes and the common electrode CE, at least a portion of the intermediate layer may be located within the opening formed by the pixel-defining layer 107. The light-emitting area of the organic light-emitting diode OLED may be defined by the opening. The intermediate layer may include an emission layer. The emission layer may include an organic material including a fluorescent or phosphorescent material for emitting red, green, blue, or white light. The emission layer may include a low molecular weight organic material or a polymer organic material, and function layers, such as a hole transport layer (HTL), a hole injection layer (HIL), an electron transport layer (ETL), an electron injection layer (EIL), and/or the like may be selectively located below and above the emission layer.

The emission layer may have a shape patterned corresponding to each of the pixel electrodes. Other layers except for the emission layer included in the intermediate layer may be variously modified, for example, to be integrally formed across a plurality of pixel electrodes.

Referring back to FIG. 4, as described above, the storage capacitor Cst is formed corresponding to the first capacitor electrode Cst1r of the bottom metal layer BML and the first part of the first active layer ACT1 of the active layer ACT and arranged to overlap a pixel electrode of another adjacent sub-pixel. Accordingly, according to one or more embodiments, a degree of freedom is relatively high in the arrangement of pixel electrodes, and thus, a display apparatus having a high degree of freedom in the arrangement of light-emitting areas may be provided.

In one or more embodiments, the first pixel electrode PEr, the second pixel electrode PEg, and the third pixel electrode PEb may be arranged diagonally and parallel to one another, in a plan view. In other words, the first pixel electrode PEr, the second pixel electrode PEg, and the third pixel electrode PEb may be arranged in parallel (e.g., may be arranged to have parallel sides) in or along a third direction crossing both the first direction (x-axis direction) and the second direction (y-axis direction), in a plan view. For example, the first pixel electrode PEr, the second pixel electrode PEg, and the third pixel electrode PEb may be arranged in parallel in a direction crossing both of the horizontal power line EDLh extending in the first direction (x-axis direction) and the vertical power line EDLv extending in the second direction (y-axis direction), in a plan view. Furthermore, the first pixel electrode PEr, the second pixel electrode PEg, and the third pixel electrode PEb may be arranged in parallel in a direction crossing both of the horizontal common voltage line ESLh extending in the first direction (x-axis direction) and the vertical common voltage line ESLv extending in the second direction (y-axis direction), in a plan view.

In one or more embodiments, the first pixel electrode PEr may overlap a portion of the scan line SL, in a plan view. Furthermore, the first pixel electrode PEr may overlap portions of the vertical common voltage line ESLv, the initialization-sensing line ISL, and the vertical power line EDLv, in a plan view. Accordingly, the first pixel electrode PEr may have an approximately triangular shape having one side extending in the first direction (x-axis direction) and another side extending in the second direction (y-axis direction).

In one or more embodiments, the second pixel electrode PEg at the center may partially overlap the first sub-pixel Pr, in a plan view. In detail, the second pixel electrode PEg may partially overlap the first capacitor electrode Cst1r of the first sub-pixel Pr, in a plan view. Furthermore, the second pixel electrode PEg may partially overlap the first active layer ACT1 of the first sub-pixel Pr, in a plan view. In other words, the second pixel electrode PEg may overlap a portion of the storage capacitor Cst of the first sub-pixel Pr.

Furthermore, the second pixel electrode PEg may partially overlap the third sub-pixel Pb, in a plan view. In detail, the second pixel electrode PEg may partially overlap the first active layer ACT1 of the third sub-pixel Pb, in a plan view. Accordingly, the second pixel electrode PEg may have a shape extending from an upper right end to a lower left end, in a plan view. In this state, the upper right end of the second pixel electrode PEg may be a portion overlapping the first sub-pixel Pr. The lower left end of the second pixel electrode PEg may be a portion overlapping the third sub-pixel Pb.

As such, the second pixel electrode PEg at the center may overlap portions of the first sub-pixel Pr and/or the third sub-pixel Pb adjacent thereto. In this state, the first pixel electrode PEr and the third pixel electrode PEb may be arranged not to overlap the second sub-pixel Pg at the center.

The third pixel electrode PEb may overlap a portion of the control line CL, in a plan view. Furthermore, the third pixel electrode PEb may overlap portions of the data lines DLg, DLb, and DLr, in a plan view. Accordingly, the third pixel electrode PEb may have an approximately triangular shape having one side extending in the first direction (x-axis direction) and another side extending in the second direction (y-axis direction). Furthermore, as the luminance of the third pixel electrode PEb as a blue pixel electrode is less than that of a red or green pixel electrode, a vertical crosstalk phenomenon by electrical interference between data voltages may not be generated even if the third pixel electrode PEb overlaps the portions of the data lines DLg, DLb, and DLr.

Furthermore, in one or more embodiments, the first pixel electrode PEr, the second pixel electrode PEg, and the third pixel electrode PEb may each be arranged not to overlap transistors of other adjacent sub-pixels. For example, the second pixel electrode PEg may be arranged not to overlap the channel portion that is a portion of the first active layer ACT1 overlapping the first transistor T1r of the first sub-pixel Pr, for example, the gate electrode of the first transistor T1r. Furthermore, the second pixel electrode PEg may also not overlap the channel portions of the second transistor T2r and the third transistor T3r of the first sub-pixel Pr. Furthermore, the second pixel electrode PEg may not overlap the channel portion of the transistors of the third sub-pixel Pb.

Similarly, it is understood that the first pixel electrode PEr and the third pixel electrode PEb are also arranged not to overlap the channel portions of the transistors of other sub-pixels.

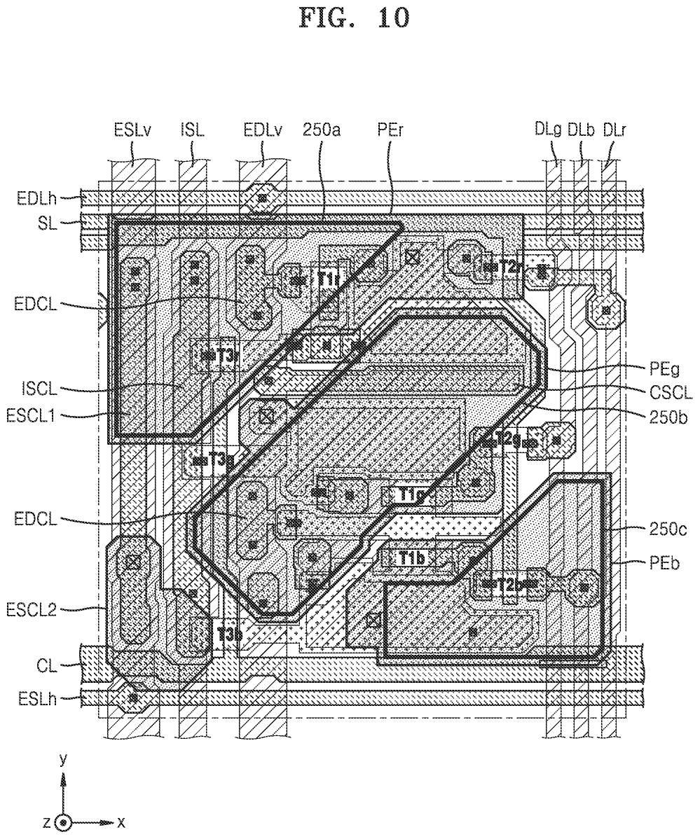

FIG. 10 is a schematic plan view of color conversion units according to one or more embodiments.

Referring to FIG. 10, the first color conversion unit 250a may be located above the first pixel electrode PEr to overlap each other. The second color conversion unit 250b may be located above the second pixel electrode PEg to overlap each other. The third color conversion unit 250c may be located above the third pixel electrode PEb to overlap each other. Accordingly, the second color conversion unit 250b may overlap, similarly to the second pixel electrode PEg described above, a portion of the first sub-pixel Pr and a portion of the third sub-pixel Pb, in a plan view. According to the arrangement of the pixel electrodes and the color conversion units, as described above, the display apparatus 1 may reduce a color-blending phenomenon. The color-blending phenomenon is that, if a plurality of pixels are arranged to display a white rectangle, as the green sub-pixels are placed most adjacent to the upper edge of the rectangle, the upper edge of the rectangle is displayed in green instead of white, as the red sub-pixels are placed most adjacent to the left edge of the rectangle, the left edge of the rectangle is displayed in red instead of white, and as the blue sub-pixels are placed most adjacent to the right edge of the rectangle, the right edge of the rectangle is displayed in blue instead of white. In the display apparatus 1 according to one or more embodiments, as the pixel electrodes and the color conversion units may partially overlap the upper portions of other adjacent sub-pixels, the pixel electrodes and color conversion units of red, green, and blue may be arranged in parallel in a diagonal direction. Accordingly, the color-blending phenomenon may be reduced.

According to one or more embodiments, a display apparatus that may display a high-quality image may be provided.

The effects of the disclosure are not limited to the above-described effects, and other various effects that are not described in the specification may be clearly understood from the following descriptions by one skilled in the art to which the present disclosure belongs.

It should be understood that embodiments described herein should be considered in a descriptive sense only and not for purposes of limitation. Descriptions of aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, with functional equivalents thereof to be included therein.

What is claimed is:

1. A display apparatus comprising:
a power line extending in a first direction, and in a second direction perpendicular to the first direction; and
a first sub-pixel having a first pixel electrode, a second sub-pixel having a second pixel electrode, and a third sub-pixel having a third pixel electrode, which display different colors from each other, and which are arranged in a third direction crossing both the first direction and the second direction, in a plan view.

2. The display apparatus of claim 1, wherein the second pixel electrode overlaps a portion of a first capacitor electrode of the first sub-pixel.

3. The display apparatus of claim 2, wherein the first capacitor electrode is electrically connected to a driving gate electrode of the first sub-pixel.

4. The display apparatus of claim 3, wherein the first capacitor electrode is at a layer under the driving gate electrode of the first sub-pixel.

5. The display apparatus of claim 1, wherein the second pixel electrode overlaps a portion of an active layer of the first sub-pixel.

6. The display apparatus of claim 5, wherein the active layer of the first sub-pixel comprises a first active layer of the first sub-pixel partially overlapping a driving gate electrode of the first sub-pixel, and
wherein the first active layer of the first sub-pixel is electrically connected to the first pixel electrode.

7. The display apparatus of claim 6, wherein a first capacitor electrode of the first sub-pixel is at a lower layer under the first active layer of the first sub-pixel to overlap the first active layer of the first sub-pixel.

8. The display apparatus of claim 1, wherein the second pixel electrode overlaps a portion of an active layer of the third sub-pixel.

9. The display apparatus of claim 8, wherein a portion of the active layer of the third sub-pixel is electrically connected to the third pixel electrode.

10. The display apparatus of claim 1, further comprising a capacitor-blocking line between a first capacitor electrode of the first sub-pixel and a first capacitor electrode of the second sub-pixel.

11. The display apparatus of claim 10, wherein the capacitor-blocking line is electrically connected to the power line.

12. The display apparatus of claim 10, wherein the capacitor-blocking line is at a same layer as gate electrodes of the first sub-pixel, the second sub-pixel, and the third sub-pixel.

13. The display apparatus of claim 12, wherein the power line comprises:
a horizontal power line extending in the first direction; and
a vertical power line extending in the second direction, and at a layer under the horizontal power line, and
wherein the capacitor-blocking line is at a same layer as the horizontal power line.

14. The display apparatus of claim 1, wherein the second sub-pixel comprises a first active layer of the second sub-pixel partially overlapping a driving gate electrode of the second sub-pixel, and
wherein the first active layer of the second sub-pixel is between a first capacitor electrode of the second sub-pixel and a first capacitor electrode of the third sub-pixel.

15. The display apparatus of claim 14, wherein the first active layer of the second sub-pixel comprises a protruding portion extending in the first direction, and
wherein the protruding portion extends to a switching gate electrode of the second sub-pixel.

16. The display apparatus of claim 14, wherein the third sub-pixel comprises a first active layer of the third sub-pixel partially overlapping a driving gate electrode of the third sub-pixel, and
wherein the first active layer of the third sub-pixel is integrally formed with the first active layer of the second sub-pixel.

17. The display apparatus of claim 16, wherein the driving gate electrode of the second sub-pixel and the driving gate electrode of the third sub-pixel face each other.

18. The display apparatus of claim 14, wherein the first active layer of the second sub-pixel is electrically connected to the power line.

19. The display apparatus of claim 1, further comprising a data line extending in the second direction,
wherein the third pixel electrode overlaps a portion of the data line.

20. The display apparatus of claim 1, further comprising:
a first color conversion unit in the first pixel electrode, and overlapping the first pixel electrode;
a second color conversion unit in the second pixel electrode, and overlapping the second pixel electrode; and
a third color conversion unit in the third pixel electrode, and overlapping the third pixel electrode.
